(19) United States
(12) Patent Application Publication
(10) Pub. No.: US 2012/0044742 A1
(43) Pub. Date: Feb. 23, 2012

(54) VARIABLE RESISTANCE MEMORY ARRAY ARCHITECTURE

(75) Inventor: Venkat Narayanan, Santa Clara, CA (US)

(73) Assignee: Micron Technology, Inc.

(21) Appl. No.: 12/859,981

(22) Filed: Aug. 20, 2010

(51) Int. Cl. G11C 11/00

(52) U.S. Cl. 365/148

(57) ABSTRACT

Memory devices, memory arrays, and methods of operation of memory arrays are disclosed. In one such memory device, a parallel selection architecture includes a control element, such as a selection transistor, in parallel with a variable resistance memory cell. Biasing of the selection transistor enables access to the memory cell for reading, programming, and/or erasing. Programming and erasing of the memory cell is accomplished through a change of resistance of the memory cell.

### TECHNICAL FIELD

The present embodiments relate generally to memory and a particular embodiment relates to variable resistance memory devices.

### BACKGROUND

Flash memory devices have developed into a popular source of non-volatile memory for a wide range of electronic applications. Flash memory devices typically use a one-transistor memory cell that allows for high memory densities, high reliability, and low power consumption. Common uses for flash memory include personal computers, flash drives, digital cameras, and cellular telephones. Program code and system data such as a basic input/output system (BIOS) are typically stored in flash memory devices for use in personal computer systems.

Flash memory density has increased and cost per bit has decreased in recent years. To increase density, memory cell size and proximity to adjacent memory cells has been reduced. This can lead to problems with disturb conditions resulting from interaction between adjacent memory cells. Additionally, flash memory is still relatively slow when compared to other forms of memory (e.g., DRAM).

Variable resistance memory, such as resistive random access memory (RRAM), is a memory technology that provides a non-volatile memory function in a variable resistance memory cell. For example, a low resistance of the memory cell indicates one state while a high resistance indicates a second state. Examples of such variable resistance memory includes metal oxide, phase change (GST), nano-filament, stiction force, mechanical deformation, polymer, molecular, and MRAM.

Conventional variable resistance memory cells are connected in series with a control element (e.g., diode, transistor). FIGS. 1A and 1B illustrate typical prior art selection architectures.

FIG. 1A shows a select diode 100 connected in series with the memory cell 101. The select line (e.g., word line) is connected to the select diode 100 and the data line (e.g., bit line) is connected to the memory cell 101. FIG. 1B shows the resistive memory cell 106 connected to the source of a select transistor 105. The word line is connected to the control gate of the select transistor 105 while the bit line is connected to the drain of the select transistor 105.

Both of these typical prior art series selection architectures experience problems. For example, the select diode selection architecture typically has current sneak paths and failure to provide adequate current and on/off ratios. The select transistor selection architecture needs an extra memory cell contact to the source of the select device.

For the reasons stated above, and for other reasons stated below that will become apparent to those skilled in the art upon reading and understanding the present specification, there is a need in the art for an improved resistive random access memory array architecture.

### BRIEF DESCRIPTION OF THE DRAWINGS

FIGS. 1A and 1B show typical prior art series selection architectures for an RRAM memory cell.

FIG. 2 shows a schematic diagram of one embodiment of a parallel selection architecture for an RRAM memory cell.

FIG. 3 shows a schematic diagram of one embodiment of an RRAM memory cell array in accordance with the parallel selection embodiment of FIG. 2.

FIG. 4 shows a schematic diagram of one embodiment of a sense operation in accordance with the parallel selection embodiment of FIG. 3.

FIG. 5 shows a schematic diagram of one embodiment of a program operation in accordance with the parallel selection embodiment of FIG. 3.

FIG. 6 shows a schematic diagram of one embodiment of an erase operation in accordance with the parallel selection embodiment of FIG. 3.

FIG. 7 shows a block diagram of one embodiment of a memory system that can incorporate the memory array of FIG. 3.

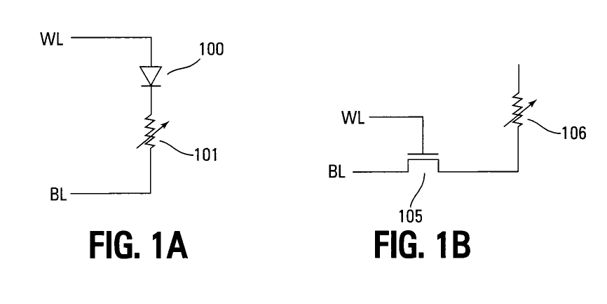

### DETAILED DESCRIPTION

In the following detailed description, reference is made to the accompanying drawings that form a part hereof and in which is shown, by way of illustration, specific embodiments. In the drawings, like numerals describe substantially similar components throughout the several views. Other embodiments may be utilized and structural, logical, and electrical changes may be made without departing from the scope of the present disclosure. The following detailed description is, therefore, not to be taken in a limiting sense.

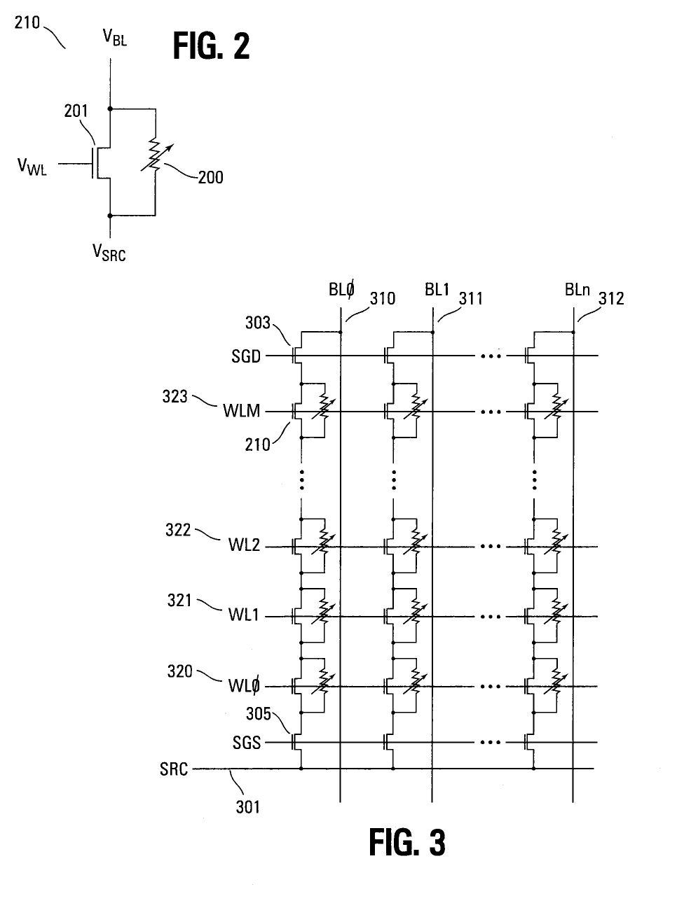

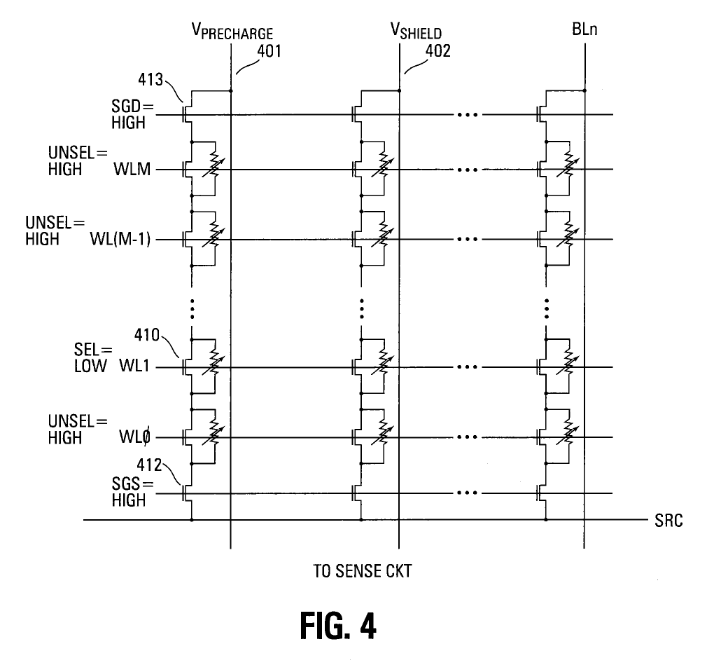

FIG. 2 illustrates a schematic diagram of one embodiment of a parallel selection architecture of an RRAM memory device 210. The memory device 210 comprises a control element, e.g., a selection transistor 201, coupled in parallel to a variable resistance memory cell, such as RRAM memory cell 200. The selection transistor 201 is biased through one or more of the select line voltage (e.g., word line) V_{WL}, the data line voltage (e.g., bit line) V_{BL}, and/or the source line voltage V_{SRC} to provide access to the memory cell 200 when the selection transistor 201 is deactivated (e.g., turned off). The embodiments of FIGS. 4-6 illustrate embodiments for sensing, programming, and erasing a parallel selected memory cell.

In one embodiment, the memory cell 200 is programmed from a high resistance device to a low resistance device by applying a particular current to the memory cell for a particular time period. The biasing of the selection transistor 201 controls the time during which the particular current is applied to the device. As will be discussed subsequently, with reference to FIGS. 4-6, the amount of current may be controlled by the source line SRC. The source line is thus performing a compliance function during the sensing, programming, and erasing operations.

FIG. 3 illustrates one embodiment of the parallel selection architecture of the RRAM memory device, as illustrated in FIG. 2, implemented in a flash NAND-style memory array. The array comprises a plurality of bit lines 310-311 organized in columns and a plurality of word lines 320-323 organized in rows. In the illustrated embodiment, WL0 320 is closest to the source line SRC 301. Alternate embodiments can use other labeling conventions.

Each series string of memory devices 210 may comprise a first select gate, e.g., select gate drain transistor 303, that controls access to a respective bit line 310. The selection transistor 201 of each memory device 210 is coupled source-to-drain in the series string with adjacent select transistors. A second select gate, e.g., select gate source transistor 305, controls access of a particular series string of memory devices to the source line 301.

FIG. 4 illustrates one embodiment of a method for a sense operation of a parallel selection RRAM memory cell in the memory array of FIG. 3. One or more bit lines 401 to be sensed may be biased at a precharge voltage. One or more bit lines 402 that are adjacent to a bit line 401 being sensed may be biased at a voltage that not only deactivates the select gate drain transistor 413 but causes those particular bit lines 402 to act as shields for the sensed bit line. The adjacent bit lines 402 shield the sensed bit lines 401 against disturb conditions that can be caused by capacitive coupling.

A selected word line 410 of one or more series-coupled strings of memory devices 210 to be sensed may be at a logical low (e.g., 0V) to keep the selection transistors 201 on the word line 410 turned off. In one embodiment, the selected word line 410 is biased at 0V that biases control gates of the selection transistors 201 coupled to that particular word line 410. The selection transistors 201 coupled to the unselected word lines, e.g., the remaining word lines of the one or more series-coupled strings of memory devices 210, may be activated (e.g., turned on) with a relatively high voltage that turns on the unselected selection transistors 201. For example, the unselected word lines can be biased at a voltage of greater than 3V. The select gate source transistor 412 and the select gate drain transistor 413 are both turned on with a relatively high voltage (e.g., >3V) to couple the sensed bit lines to their respective series-coupled strings of memory devices 210.

If the memory cell is programmed (e.g., low resistance), the selected bit line 401 should be pulled down by the conductive memory cell 200 to a relatively lower voltage. The sense circuitry, e.g., sense amplifier circuitry (not shown in FIG. 4), coupled to the bit lines will detect the bit line 401 being pulled down from the precharge level to the relatively lower voltage and determine that the selected resistive memory cell 200 is programmed. For example, the sense circuitry may detect that a voltage of the bit line 401 has fallen below some particular value after some particular time and deem the selected memory cell 200 to be programmed.

If the memory cell 200 is not programmed (e.g., high resistance), the selected bit line 401 should remain at or near the precharge voltage. The sense circuitry detects that the selected bit line is at or near the precharge voltage and determines that the selected memory cell is not programmed. To continue the foregoing example, the sense circuitry may detect that the voltage of the bit line 401 has remained above the particular value after the particular time and deem the selected memory cell 200 to be not programmed.

While the previous discussion refers to a memory cell that is binary (e.g., either logical 1 or 0), an alternate embodiment can use the resistive nature of the memory cell in a multilevel scheme. For example, different resistive values can be programmed into the memory cell, each resistive value indicating a different data state (e.g., 00, 01, 10, 11). The different resistances, when read with the above procedure, will cause the precharge bit line to be pulled down by different voltages from the precharge voltage and at different rates. The sense circuitry can then detect the voltage differences from the precharge voltage and determine the data state being indicated by a particular resistance. In addition to sensing voltage levels as described above, the sense circuitry may alternatively look to differing current levels between the differing data states for either binary or multilevel schemes.

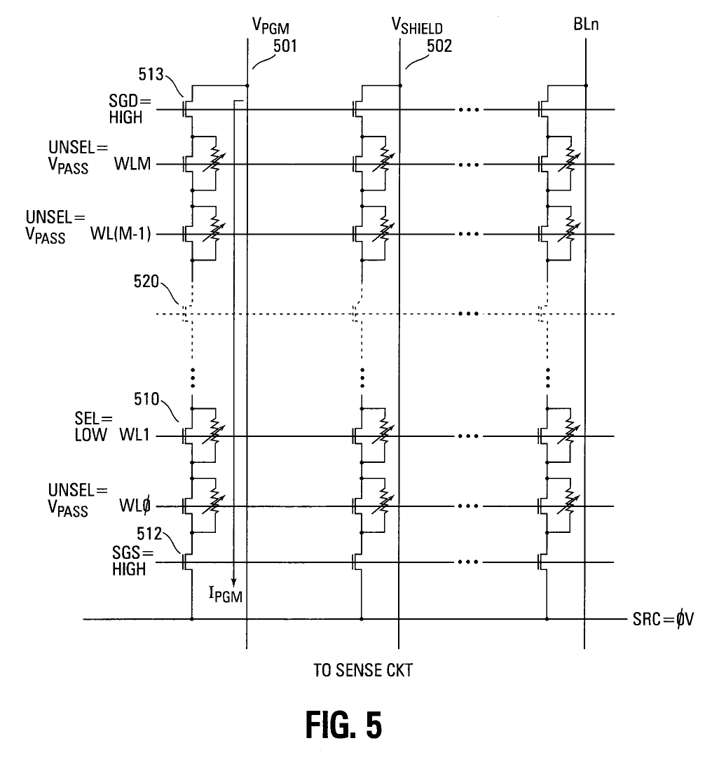

FIG. 5 illustrates one embodiment of method for a program operation of a parallel selection RRAM memory cell in the memory array of FIG. 3. In this embodiment, the selected word line 510 of one or more series-coupled strings of memory devices 210 to be programmed may be biased at a logical low (e.g., biased at 0V). Thus, the selection transistor 201 of each memory cell 200 coupled to the selected word line 510 is turned off. The unselected word lines, e.g., the remaining word lines of the one or more series-coupled strings of memory devices 210, may be biased at a pass voltage (e.g., V_{PASS}) so that selection transistors 201 coupled to those word lines are rendered conductive but not high enough to cause programming of the memory cells. For selected bit lines 501, the select gate source transistor 512 and the select gate drain transistor 513 are both turned on, such as with a relatively high voltage on their respective gates, to couple the selected bit lines 501 to their respective series-coupled strings of memory devices 210. The select gate source transistor 512 may act as a compliance device that performs a compliance function (discussed subsequently) in the series string.

Unselected bit lines 502 may be biased at V_{SHIELD} (e.g., 0V) so that they provide a disturb shield function. V_{SHIELD} may be selected to turn off the select gate source transistor 512 and the select gate drain transistor 513 to isolate the unselected bit lines 502 from their respective series-coupled strings of memory devices. The program voltage, V_{PGM}, may be applied to one or more selected bit lines 501. A program current, I_{PGM}, can now flow through the series string of selection transistors to the source line SRC. Since the selection transistors for the unselected word lines are all turned on, they provide I_{PGM} a lower resistance path to SRC as compared to the unselected memory cells that are at a high resistance in their unprogrammed state. The selection transistor 201 of the selected word line 510 is turned off so that it provides a greater resistance than the selected memory cell. I_{PGM} flows through the selected resistive memory cell to the SRC that is at a voltage less than V_{PGM} (e.g., 0V). The current flow reduces the selected memory cell's resistance to a programmed state.

Programming a memory cell may use a particular current for a particular length of time. The select gate source transistor 512 may control the I_{PGM} level and timing so that the program current is in compliance with the desired conditions for programming.

In an alternate embodiment, at least one helper transistor 520 is coupled in each series string. These helper transistors 520 can be turned on during a program operation in order to increase the program current to the selected memory cells.

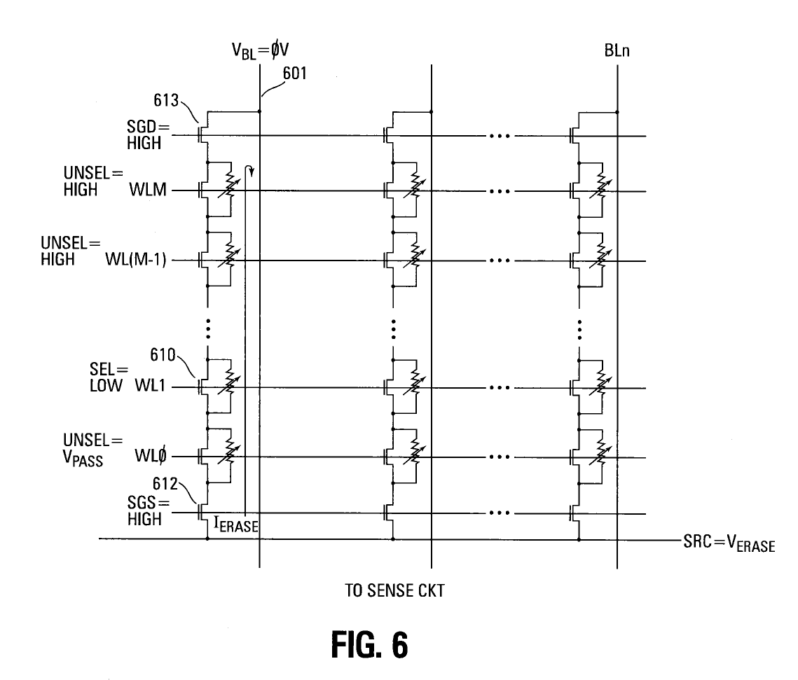

FIG. 6 illustrates one embodiment of a method for an erase operation of a parallel selection RRAM memory cell in the memory array of FIG. 3. This operation is complementary to the program operation in that the erase current, I_{ERASE}, flows from the SRC, that may be biased at V_{ERASE} (e.g., supply voltage) to a selected bit line 601. The memory cells that are coupled to word lines selected with a low voltage (e.g., 0V) will be erased. The word lines may be biased in a substantially similar fashion as in the programming operation: the selected word line 610 may be biased so that its selection transistors 201 are turned off (e.g., 0V), and the unselected word lines may be biased so that their selection transistors 201 are turned on. Both the select gate source transistor 612 and the select gate drain transistor 613 are turned on and the select gate source transistor 612 again may act as a compliance device to regulate I_{ERASE}. The selected bit line 601 may be biased at a voltage (e.g., 0V) that is less than V_{ERASE}. The erase current I_{ERASE} can now flow from SRC to the selected bit line 601 for the particular time necessary to increase the resistance of the selected memory cell 210 to the unprogrammed state, as controlled by the select gate source transistor 612 acting as a compliance device.

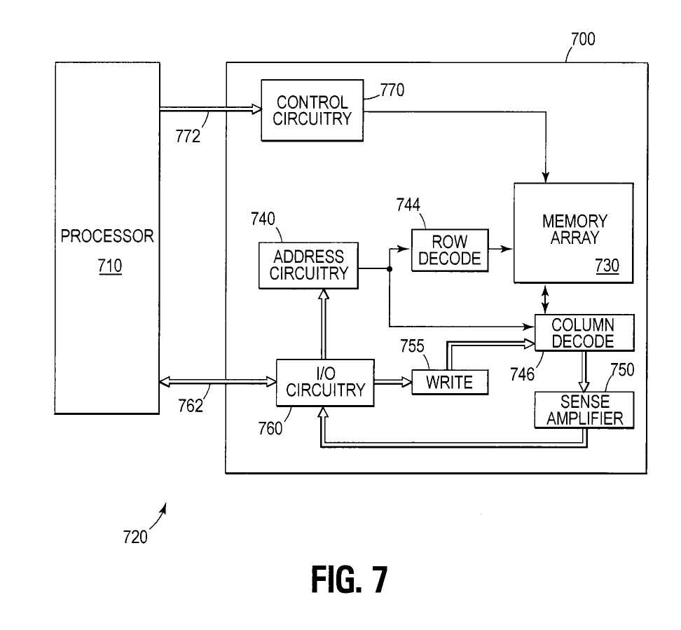

FIG. 7 illustrates a functional block diagram of a memory 700. The memory 700 is coupled to an external processor 710. The processor 710 may be a microprocessor or some other type of controller. The memory 700 and the processor 710 form part of a memory system 720. The memory 700 has been simplified to focus on features of the memory that are helpful in understanding the present embodiments.

The memory 700 includes an array 730 of memory devices 210 (e.g., resistive memory cells with select gate) such as the array of FIG. 3. The memory array 730 may be arranged in banks of word line rows and bit line columns. In one embodiment, the columns of the memory array 730 comprise series strings of memory devices 210.

Address buffer circuitry 740 is provided to latch address signals provided through I/O circuitry 760. Address signals are received and decoded by a row decoder 744 and a column decoder 746 to access the memory array 730. It will be appreciated by those skilled in the art with the benefit of the present description that the number of address input connections depends on the density and architecture of the memory array 730. That is, the number of addresses increases with both increased memory cell counts and increased bank and block counts.

The memory 700 reads data in the memory array 730 by sensing voltage or current changes in the memory array columns using sense amplifier circuitry 750. The sense amplifier circuitry 750, in one embodiment, is coupled to read and latch a row of data from the memory array 730. Data input and output buffer circuitry 760 is included for bidirectional data communication as well as the address communication over a plurality of data connections 762 with the controller 710. Write circuitry 755 is provided to write data to the memory array.

Memory control circuitry 770 decodes signals provided on control connections 772 from the processor 710. These signals are used to control the operations on the memory array 730, including data read, data write (program), and erase operations. The memory control circuitry 770 may be a state machine, a sequencer, or some other type of controller to generate the memory control signals. In one embodiment, the memory control circuitry 770 is configured to control the timing and generation of voltages for the methods for sensing, programming, and erasing of memory cells.

The memory device illustrated in FIG. 7 has been simplified to facilitate a basic understanding of the features of the memory. A more detailed understanding of internal circuitry and functions of resistive memories are known to those skilled in the art.

### CONCLUSION

In summary, one or more embodiments provide parallel selection of a memory cell. With the memory cell coupled in parallel with a selection transistor, for example, the resulting memory device can be used in a NAND-style memory array.

Although specific embodiments have been illustrated and described herein, it will be appreciated by those of ordinary skill in the art that any arrangement that is calculated to achieve the same purpose may be substituted for the specific embodiments shown. Many adaptations of the invention will be apparent to those of ordinary skill in the art. Accordingly, this application is intended to cover any adaptations or variations of the invention.

What is claimed is:

1. A memory device comprising:
a control element; and
a variable resistance memory cell coupled in parallel with the control element.

2. The memory device of claim 1 wherein the control element is a transistor.

3. The memory device of claim 2 wherein biasing of a control gate of the transistor provides access to the variable resistance memory cell.

4. The memory device of claim 3 wherein a drain of the transistor is configured to be selectively coupled to a data line and a source of the transistor is configured to be selectively coupled to a source line.

5. The memory device of claim 1 wherein deactivation of the transistor enables current to flow through the memory cell for programming, sensing, and/or erasing the memory cell.

6. The memory device of claim 5 wherein current flowing in a first direction increases a resistance of the memory cell.

7. The memory device of claim 6 wherein current flowing in a second direction decreases the resistance of the resistive memory cell.

8. The memory device of claim 6 wherein the memory cell is configured to be programmed with greater than two states such that each state is indicated by a different resistance.

9. A memory array comprising:
a plurality of series strings of memory devices, each memory device comprising:
a selection transistor; and
a variable resistance memory cell coupled in parallel with the selection transistor.

10. The memory array of claim 9 wherein each series string of memory devices comprises the selection transistors being coupled in series source-to-drain with adjacent selection transistors.

11. The memory array of claim 9 wherein each series string of memory devices is coupled to a data line through a first select gate and to a source line through a second select gate.

12. The memory array of claim 11 wherein the second select gate is configured to act as a compliance device.

13. The memory array of claim 12 wherein the compliance device is configured to control a program current during a programming operation.

14. The memory array of claim 9 wherein a control gate of each selection transistor is coupled to a select line to form rows of memory devices with adjacent series strings of memory devices.

15. A method of operation of an array of memory cells, the method comprising:
biasing a selected data line at a precharge voltage;
biasing a control gate of a selected memory device, that includes a variable resistance memory cell, to turn off a transistor coupled in parallel to the memory cell;
biasing control gates of unselected memory devices at a voltage that activates the unselected memory devices; and
determining a state of the memory cell in response to one of a detected voltage of the selected data line or a detected current on the selected data line.

16. The method of claim 15 and further including biasing select gates such that the select gates are activated.

17. The method of claim 15 and further comprising biasing adjacent data lines to the selected data line at a shield voltage.

18. The method of claim 15 wherein a programmed memory cell comprises a relatively low resistance and an unprogrammed memory cell comprises a relatively high resistance.

19. The method of claim 18 wherein the relatively low resistance of the selected memory cell results in the data line being pulled down from the precharge voltage to a relatively lower voltage during a sense operation.

20. The method of claim 18 and further including determining one of a plurality of states programmed to the memory cell in response to one of a voltage difference on the selected data line or a current level on the selected data line.

21. The method of claim 20 wherein the voltage difference is indicative of a resistance of the memory cell.

22. A method of operation of an array of memory cells, the method comprising:
biasing a control gate of a selected memory device to deactivate a control element of the selected memory device;
biasing control gates of unselected memory devices at a pass voltage;
biasing a data line coupled to the selected memory device at a program voltage; and
biasing a source line at a voltage that is less than the program voltage.

23. The method of claim 22 and further including biasing select gates at a voltage that activates the select gates.

24. The method of claim 22 wherein a first of the select gates is configured to control a programming current through the selected memory device.

25. The method of claim 24 wherein the first select gate is a select gate source transistor that is coupled between the selected memory device and the source line and is configured to perform a compliance function.

26. The method of claim 22 and further including activating a helper transistor in a series string with the selected memory device such that a programming current is increased.

27. A method of operation of an array of memory cells, the method comprising:
biasing a control gate of a selected memory device to deactivate a control element of the selected memory device;
biasing control gates of unselected memory devices at a pass voltage;
biasing a source line at an erase voltage; and
biasing a data line coupled to the selected memory device at a voltage that is less than the erase voltage.

28. The method of claim 27 and further including biasing select gates at a voltage that activates the select gates;

29. The method of claim 27 wherein the pass voltage turns on the unselected memory devices.

30. The method of claim 29 wherein the unselected memory devices comprise a selection transistor and a memory cell, wherein the pass voltage activates the selection transistors.

31. The method of claim 27 wherein an erase current is created through a memory cell of the selected memory device such that a resistance of the memory cell is increased.
